(19) United States
(12) Patent Application Publication
(10) Pub. No.: US 2019/0243135 A1
(43) Pub. Date: Aug. 8, 2019

(54) HEAD UP DISPLAY, LIGHT-EMITTING THIN FILMS AND METHOD FOR FORMING THE SAME

(71) Applicant: National Taiwan University, Taipei (TW)

(72) Inventors: Ching-Fuh Lin, Taipei (TW); Tsung-Yo Tsai, Taipei (TW); Chun-Yu Lin, Taipei (TW)

(21) Appl. No.: 16/231,814

(22) Filed: Dec. 24, 2018

(30) Foreign Application Priority Data
Feb. 2, 2018 (TW) 107103904

(51) Int. Cl. G02B 27/01; H01L 33/26; G03B 21/20; H05B 33/10; H01L 51/56; H01L 33/50

(52) U.S. Cl. CPC G02B 27/0101; H01L 33/26; H01L 33/502; H05B 33/10; H01L 51/56; G03B 21/206

(57) ABSTRACT

A light-emitting thin film is provided with one or more light-emitting materials and a host. Each light-emitting material is capable of absorbing photons or electromagnetic waves and re-radiating photons or electromagnetic waves after the absorption. The host is used to eliminate grain boundaries and mitigate scattering of the light-emitting materials after the film is formed. Preferably the light-emitting thin film is made of a solution process. A head-up display using the light-emitting thin film is also disclosed.

### CROSS-REFERENCE TO RELATED APPLICATIONS

The entire contents of Taiwan Patent Application No. 107103904, filed on Feb. 2, 2018, from which this application claims priority, are expressly incorporated herein by reference.

### BACKGROUND OF THE INVENTION

### 1. Field of the Invention

The present invention relates to light-emitting thin films and their manufacturing methods and applications.

### 2. Description of Related Art

Projection apparatuses, such as head-up displays used for vehicles, are divided into two types: transmission type and reflection type. The former includes a lens module and a projection device. The projection device projects an image and the lens module focuses the image on a position about 1 meter behind a front windshield of a car, so that the driver not only perceives information shown on the projected image but also can view the sight behind the front windshield. The lens module plays an important role for a transmission type of head-up display. The optical design of lens module determines the cost and where the image is projected. The lens module needs multiple lenses and complicated optical design to project the image in a far distance, and the cost is hence increased. The projection device also needs a high-powered light source because of its intensity being weakened by the lens module, and hence the cost is further increased. As a result of high cost, only premium cars equip with the transmission type of head-up displays.

In contrast, a reflection type of head-up display includes a projection device and a reflecting film The projection device utilizes a light-emitting array to project an image having driving information on the reflecting film, which is stuck on the front windshield. This type of head-up display has advantages including free of lens module, simple optical design, and easy installation, and hence it is more popular than the transmission type. However, the reflecting film has a limited view angle and must be installed at a position allowing the viewer within the view angle; otherwise the driver cannot see the projected image. In addition, a high degree of reflection is necessary for the reflecting film and hence the degree of transmission is low in relation to the reflection. Accordingly the sight outside of car cannot be clearly seen through the reflecting film. Due to the above-mentioned drawbacks, conventional reflecting film typically has a small area and the position of which cannot obstruct the driver's view, seriously limiting the applications.

### SUMMARY OF THE INVENTION

An object of this invention is to provide a light-emitting thin film and its producing method and application.

According to an aspect of this invention, a light-emitting thin film is provided with one or more light-emitting materials and a host. Each light-emitting material is capable of re-radiating photons or electromagnetic radiation after the absorption of photons or electromagnetic radiation. The host is used for eliminating grain boundaries and scattering of the one or more light-emitting materials.

Preferably, the one or more light-emitting materials comprise organic dyes made of non-rare earth elements, and the host keeps the polarity of the organic dyes and hence keeps absorption and radiation wavelength range as in the liquid form. In one embodiment, the organic dyes comprise C545T or DCJTB. In one embodiment, the host comprises silica gel or silicon dioxide formed by spin-on glass coating. In one embodiment, the host comprises a polymer. In one embodiment, the polymer comprises polyvinylpyrrolidone (PVP), epoxy, polymethylmethacrylate (PMMA), or polydimethylsiloxane (PDMS). In one embodiment, the one or more light-emitting materials comprise zinc oxide (ZnO). In one embodiment, the light-emitting thin film is one layer of a multi-layered lens and is used to absorb blue light to protect an eye being damaged.

According to another aspect of this invention, a method to produce a light-emitting thin film is provided with the steps of: dissolving one or more organic dyes and a host in a solvent to form a light-emitting solution; forming the light-emitting solution on a substrate; and removing the solvent from the light-emitting solution to form a light-emitting thin film; wherein each organic dye is capable of re-radiating photons or electromagnetic radiation after the absorption of photons or electromagnetic radiation, and the host eliminates grain boundaries and scattering of the one or more light-emitting materials and keeps the polarity and absorption and radiation wavelength range of the organic dyes as in the liquid form after the light-emitting thin film is formed.

In one embodiment, the host comprises silica gel or liquid form of silicon dioxide, which is spin-coated on the substrate. In one embodiment, the host comprises a polymer. In one embodiment, the solvent comprises ethanol, chloroform, dichloromethane, or other solvents capable of dissolving the one or more organic dyes and polymer. In one embodiment, the organic dyes comprise non-rare earth elements. In one embodiment, method for forming the light-emitting solution on the substrate comprising spin coating, dip coating, ink jet printing, screen printing, comma coating, or roll coating. In one embodiment, the substrate is made of glass, epoxy, quartz, plastics, or other materials that will not react with the light-emitting thin film.

According to another aspect of this invention, a head-up display is provided with a projection device and a light-emitting thin film The projection device is used for emitting a light beam. The light-emitting thin film comprises one or more light-emitting materials and a host. Each light-emitting material is capable of re-radiating photons or electromagnetic radiation after the absorption of photons or electromagnetic radiation. The host is used for eliminating grain boundaries and scattering of the one or more light-emitting materials.

### BRIEF DESCRIPTION OF THE DRAWINGS

FIG. 1 is a flow chart illustrates a method for producing a light-emitting thin film in accordance with a preferred embodiment of this invention.

FIG. 2 is a transmission measurement and comparison between a commercial thin film and a green light-emitting thin film of this invention.

FIG. 3 is a transmission measurement and comparison between a commercial thin film and a red light-emitting thin film of this invention.

FIG. 4 illustrates a head-up display in accordance with an embodiment of this invention.

FIG. 5 is a picture showing a head up display with a green light-emitting thin film in accordance with an embodiment of this invention.

FIG. 6 is a picture showing a head up display with a green light-emitting thin film in accordance with an embodiment of this invention.

FIG. 7 shows the absorption of the green light-emitting thin film in accordance with an embodiment of this invention.

FIG. 8 illustrates a micro light-emitting diode array in accordance with an embodiment of this invention.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components. Wherever possible, the same or similar reference numbers are used in drawings and the description to refer to the same or like parts.

An embodiment of this invention provides a light-emitting thin film, which comprises one or more light-emitting materials and a host. Preferably, the light-emitting thin film is produced by a solution method, in which both the one or more light-emitting materials and the host are dissolved in a solvent to form a light-emitting solution, which is then formed on a substrate. After that, a light-emitting thin film is formed by removing (e.g., drying) the solvent from the light-emitting solution. In particular, the host is used to keeps the optical performance of light-emitting materials in the light-emitting thin film as the performance of which in light-emitting solution. In addition, the host can eliminate scattering of the light-emitting materials after the light-emitting thin film is formed.

According to embodiments of this invention, the light-emitting materials are photoluminescent materials which re-radiate photons (electromagnetic radiation) after the absorption of photons (electromagnetic radiation). According to embodiments of this invention, the light-emitting materials can be organic or inorganic light-emitting materials. In some embodiments, the light-emitting materials are inorganic light-emitting materials, such as zinc oxide (ZnO). In some embodiments, the light-emitting materials are organic dyes comprising non-rare earth elements. In addition, the host keeps the polarity of the organic dyes and hence keeps absorption and radiation wavelength range as it in the liquid form.

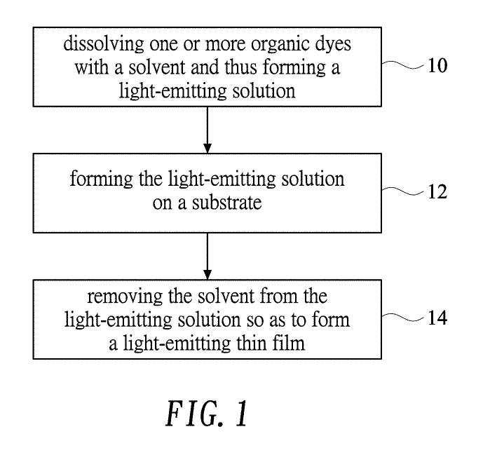

FIG. 1 is a flow chart showing a method for producing a light-emitting thin film in accordance with an embodiment of this invention. Referring to FIG. 1, the method comprises several steps. In step 10, one or more organic dyes and a host are dissolved in a solvent and thus a light-emitting solution is formed. The organic dyes are preferably non-rare earth elements, which can re-radiate photons (electromagnetic radiation) after the absorption of photons (electromagnetic radiation). In one embodiment, the temperature for dissolution ranges between 30° C. and 200° C. In one embodiment, the dissolution time ranges between 30 min and 5 hours.

Referring to FIG. 1, in step 12, the light-emitting solution is then formed (e.g., coated) on a substrate. In one embodiment, the host comprises silica gel. In one embodiment, the host comprises a liquid form of silicon dioxide and is spinning coated on the substrate. In one embodiment, the host comprises a polymer, which preferably has a good film-forming and cladding properties. In one embodiment, the polymer comprises polyvinylpyrrolidone (PVP) or epoxy. In one embodiment, the solvent comprises ethanol, chloroform, dichloromethane, or other solvents capable of dissolving the one or more organic dyes and polymer. In one embodiment, the weight ratio of the organic dyes to the polymer ranges between 1:200 and 1:20000. In one embodiment, method for forming the light-emitting solution on the substrate comprises, but is not limited to, spin coating, dip coating, ink jet printing, screen printing, comma coating, or roll coating. In one embodiment, the light-emitting solution is formed on the substrate by spin coating and the coating time is between 10 sec and 3 min. In one embodiment, the substrate is transparent and can be made of glass, epoxy, quartz, plastics, or other materials that will not react with the light-emitting thin film

Referring to FIG. 1, in step 14, the solvent is removed from the light-emitting solution so as to form a light-emitting thin film. In one embodiment, the solvent is removed from the light-emitting solution by natural (air) seasoning. In one embodiment, the time for drying ranges between 30 min and 20 hr. The light-emitting thin film is formed after the solvent is removed. The host can eliminate or reduce scattering of the light-emitting materials after the light-emitting thin film is formed. The light-emitting materials having scattering will cause an object cannot be clearly seen and looks like viewing the object through a ground glass (a glass whose surface has rough finish).

Two particular examples are provided as follows to illustrate light-emitting thin films and their manufacturing method of this invention.

In a first embodiment, a green light-emitting thin film and its producing method are disclosed.

Firstly, an organic dye, C545T, is dissolved with a proper solvent, e.g., ethanol In other embodiments, the solvent ethanol can be replaced by another capable of dissolving the organic dye C545T. The full name of C545T is 10-(2-Benzothiazolyl)-2,3,6,7-tetrahydro-1,1,7,7-tetramethyl-1H,5H,11H-(1)benzopyropyrano (6,7-8-I,j)quinolizin-11-one.

After that, the solution of C545T and solvent is agitated for 30 min so that C545T is completely dissolved and a light-emitting solution capable of emitting green light is formed. A polymer, such as polyvinylpyrrolidone (PVP), is then added into the above light-emitting solution.

After that, a heating plate is preheated to 60° C. and then used to heat the light-emitting solution. During the heating, the light-emitting solution is agitated until the polyvinylpyrrolidone is completely dissolved.

A transparent substrate is then prepared. The transparent substrate can be, but is not limited to, a transparent plastic substrate. The transparent substrate is then segmented and washed. The substrate can be cleaned by deionized water and an ultrasonic cleaner and then dried by a nitrogen spray gun. The light-emitting solution capable of emitting green light is then spin-coated on the transparent substrate with a speed between 500 rpm and 9000 rpm for 10 sec.

After that, the transparent substrate is placed under atmosphere, so as to evaporate the solvent from the light-emitting solution and thus gradually form a light-emitting thin film capable of emitting green light. Finally, a waterproof layer can be coated on the above light-emitting thin film. The waterproof layer is preferably made of a material that will not react with the light-emitting materials, so that the emission wavelength range of the light-emitting thin film will not be altered.

In a second embodiment, a red light-emitting thin film and its producing method are disclosed.

Firstly, an organic dye, DCJTB, is dissolved with a proper solvent, e.g., dichloromethane In other embodiments, other solvents capable of dissolving the organic dye can be used DCJTB. The full name of DCJTB is 2-tert-Butyl-4-(dicyanomethylene)-6-[2-(1,1,7,7-tetramethyljulolidin-9-yl)vinyl]-4H-pyran.

After that, the solution of DCJTB and solvent is agitated for 30 min so that DCJTB is completely dissolved and a light-emitting solution capable of emitting red light is formed. A polymer, such as polyvinylpyrrolidone (PVP), is then added into the above light-emitting solution.

After that, a heating plate is preheated to 60° C. and then used to heat the light-emitting solution. During the heating, the light-emitting solution is agitated until the polyvinylpyrrolidone is completely dissolved.

A transparent substrate is then prepared. The transparent substrate can be, but is not limited to, a transparent plastic substrate. The transparent substrate is then segmented and washed. The substrate can be cleaned by deionized water and an ultrasonic cleaner and then dried by a nitrogen spray gun. The light-emitting solution capable of emitting red light is then spin coated on the transparent substrate with a speed between 500 rpm and 9000 rpm for 10 sec.

After that, the transparent substrate is placed under atmosphere, so as to evaporate the solvent from the light-emitting solution and thus gradually form a light-emitting thin film capable of emitting red light. Finally, a waterproof layer can be coated on the above light-emitting thin film. The waterproof layer is preferably made of a material that will not react with the light-emitting materials, so that the emission wavelength range of the light-emitting thin film will not be altered.

Although the light-emitting thin film of either first or second embodiment emits a single color beam within a wavelength interval, in other embodiments two or more organic dyes may be used so that the produced light-emitting thin film can emit two or more color light beams with one or more wavelength intervals.

In the first and second embodiment, the organic dyes C545T and DCJTB are used to produce the light-emitting thin film. The organic dyes C545T and DCJTB are dissolved in proper solvents such as ethanol and dichloromethane to form photoluminescent light-emitting solutions with high conversion efficiency. After that, a polymer such as polyvinylpyrrolidone (PVP) is added into the light-emitting solution. The polyvinylpyrrolidone has good solubility and can be dissolved in the light-emitting solution after several minutes of agitation. Polyvinylpyrrolidone is a good film-forming and cladding agent, which covers the organic dynes so as to keep their optical performance as in the liquid form after the light-emitting thin film is formed. The produced light-emitting thin solution is then spin coated on the transparent substrate, and a green or red light-emitting thin film can be formed after the solvent evaporates from the solution. The produced light-emitting thin films are investigated, and the results show that the produced light-emitting thin films can re-radiate apparent photons under optical pumping and have good transmission within the complete visible spectral range.

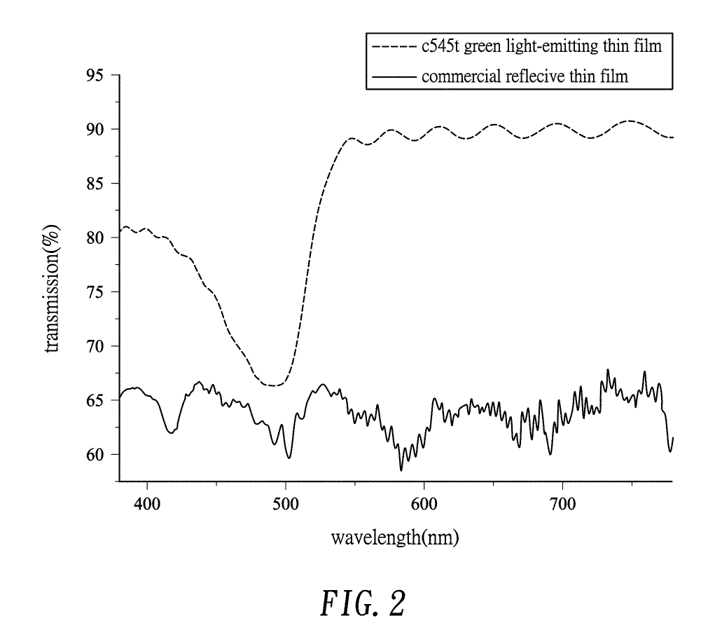

FIG. 2 is a transmission measurement and comparison between a commercial reflective thin film and the green light-emitting thin film produced by this invention. As shown in FIG. 2, the transmission (%) of the green light-emitting thin film produced by this invention is greater than that of commercial reflective thin film within the whole visible spectrum. In particular, the transmission (%) of the green light-emitting thin film produced by this invention can reach 80% or more between wavelength 530 nm and 750 nm, and the transmission (%) is more than 90% at wavelength 555 nm.

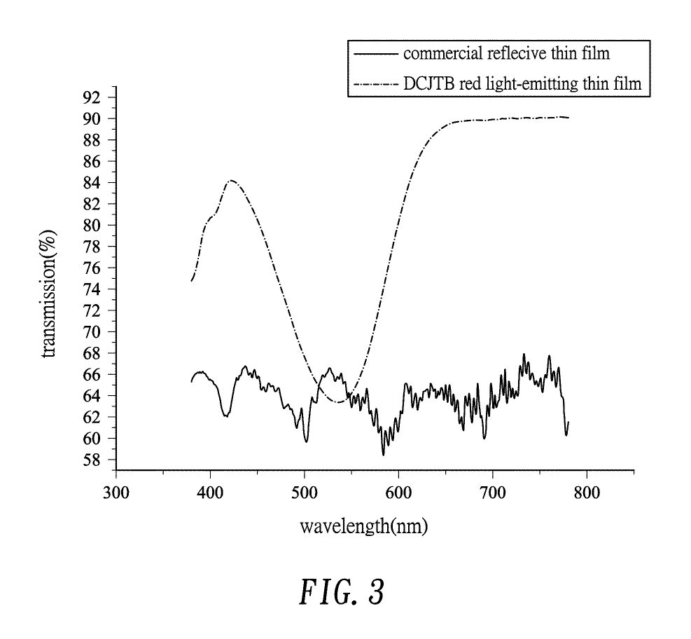

FIG. 3 is a transmission measurement and comparison between a commercial reflective thin film and the red light-emitting thin film produced by this invention. As shown in FIG. 3, the transmission (%) of the green light-emitting thin film produced by this invention is greater than that of commercial reflective thin film within most of visible spectrum. In particular, the transmission (%) of the red light-emitting thin film produced by this invention can reach 80% or more between wavelength 600 nm and 750 nm.

Accordingly, embodiments of this invention provide light-emitting thin films, which are photoluminescent films having high transmission and can absorb a color light that is less sensible to human eye and emit another color light that is high sensible to human eye. Within the visual spectrum, the human eye responds more to some wavelengths of light than others. This response of the eye is represented by the luminosity function. A luminosity function or luminous efficiency function describes the average spectral sensitivity of human visual perception of brightness. The visual sensitivity of the human eye for different colors is ordered from high to low as follows: green>yellow>orange>red. The maximum visual sensitivity of the human eye is at a wavelength of 555 nm (yellow green). The light-emitting thin films produced by this invention can absorb a color light that is less sensible to human eye and emit another color light that is high sensible to human eye. For example, the green light-emitting thin film produced by this invention can absorb blue light having low visual sensitivity to the human eye and emit green light having high visual sensitivity to the human eye.

The light-emitting thin films produced by this invention can have many applications. In one embodiment, the red light-emitting thin film produced by this invention can absorb a color light with a wavelength less than 550 nm and emit a red color light, which may be used for warning or other applications.

In some embodiments, the light-emitting thin films produced by this invention are used for head-up display due to features of high transmission and being capable of emitting a light with high visual sensitivity to the human eyes.

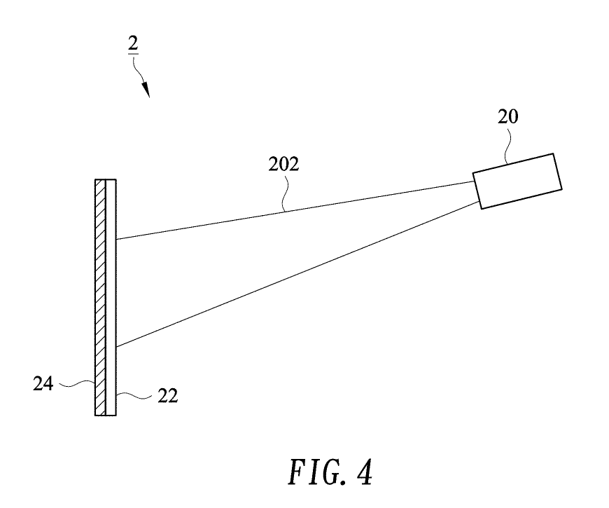

FIG. 4 is a diagram illustrating a head-up display 2 in accordance with an embodiment of this invention. Referring to FIG. 4, the head-up display 2 comprises a projection device 20 and a light-emitting thin film 22. The projection device 20 can emit a light beam 202 having driving information. In one embodiment, the light beam 202 is a colored light beam with specific wavelength interval. In one embodiment, the light-emitting thin film 33 comprises one or more light-emitting materials and a host, in which the light-emitting materials are photoluminescent materials that re-radiate photons (electromagnetic radiation) after the absorption of photons (electromagnetic radiation), and the host can the scattering of the light-emitting materials after the light-emitting thin film is formed. In this embodiment, the light-emitting thin film 22 can be formed on a substrate 24, which can be the above-mentioned transparent plastic substrate or other substrates.

Referring to FIG. 4, the one or more light-emitting materials of the light-emitting thin film 22 comprises organic dyes. In one embodiment, the organic dyes comprise C545T or DCJTB. In one embodiment, the host comprises silica gel or spin-coated silicon dioxide (SiO₂). In one embodiment, the host comprises a polymer. In one embodiment, the polymer comprises polyvinylpyrrolidone (PVP), polymethylmethacrylate (PMMA), polydimethylsiloxane (PDMS). In one embodiment, the host comprises zinc oxide (ZnO).

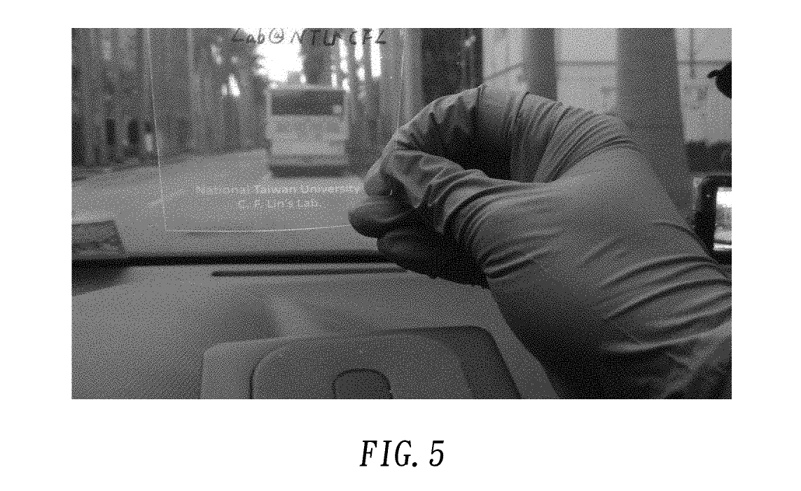

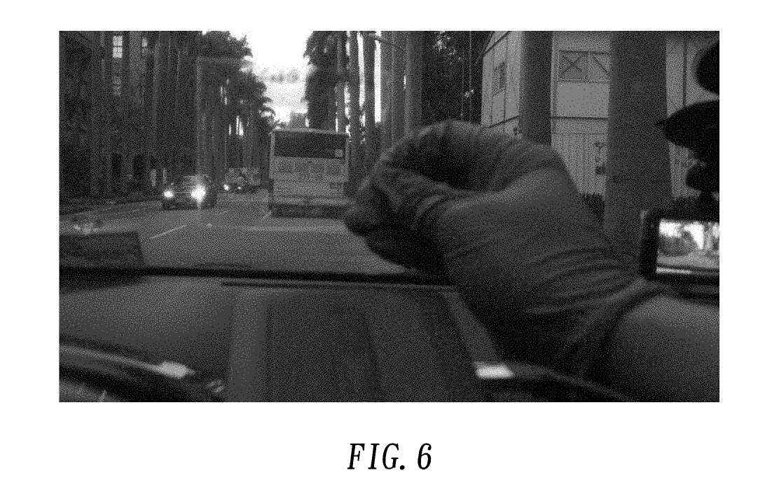

FIGS. 5 and 6 are pictures taken by a camera to show that the green light-emitting thin film produced in the first embodiment is stuck on a windshield for being used as a reflective film of a head-up display. Because the camera has only one focal length, FIG. 5 shows to focus on the light-emitting thin film and FIG. 6 shows to focus on a bus outside the windshield. Referring to FIG. 5, the light-emitting thin film absorbs blue light emitted from the projection device and emits a green light. The projected driving information, “National Taiwan University C. F. Lin's Lab,” can be clearly seen on the light-emitting thin film. Referring to FIG. 6, because the light-emitting thin film has high transmission, the bus outside the windshield can be also clearly seen through the light-emitting thin film.

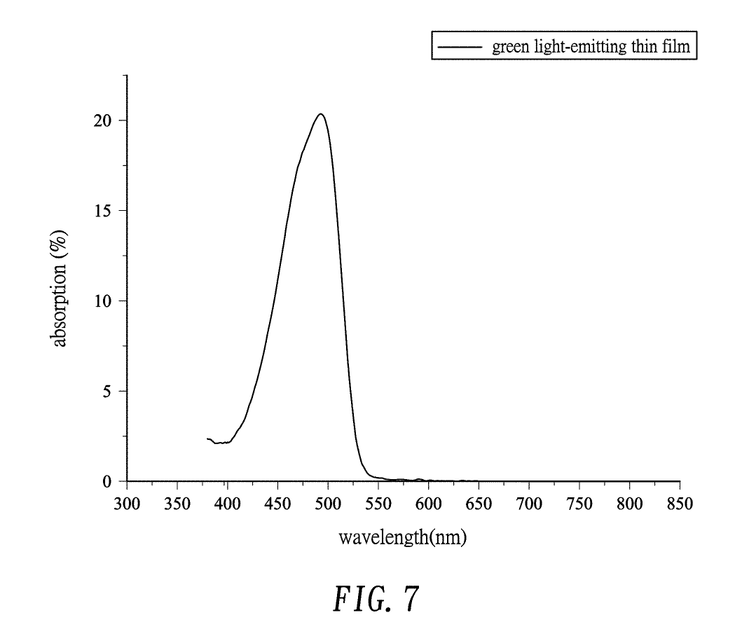

While embodiments of the present invention are described with specific regard to application for head-up displays, it is to be appreciated that embodiments of the invention are not so limited and that certain embodiments may also be applicable to other devices. FIG. 7 shows the absorption of the green light-emitting thin film produced by the first embodiment of this invention. Referring to FIG. 7, the absorption spectrum has a peak at a wavelength of 490 nm, which belongs to blue interval. In one embodiment, the green light-emitting thin film can be formed on a lens of a glass or used as one layer of the multi-layered lens. Blue light can be absorbed by the green light-emitting thin film to avoid damaging the eyes.

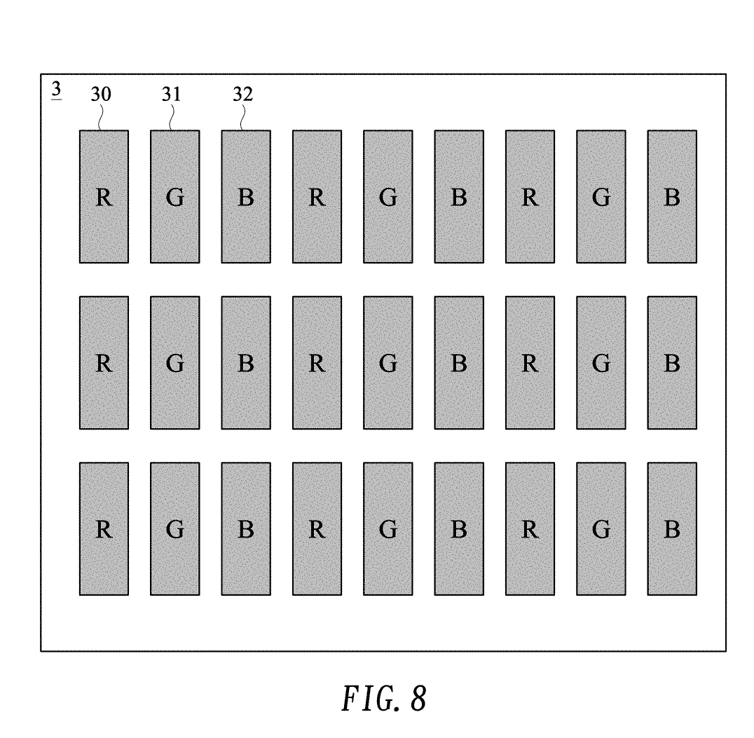

This invention provides light-emitting thin films having a good film-forming property and having free of grain boundaries. FIG. 8 is a diagram showing a micro light-emitting diode array 3 in accordance with an embodiment of this invention. Referring to FIG. 8, the micro light-emitting diode array 3 consists of red pixels (R), green pixels (G), and blue pixels (B). Each pixel comprises an epitaxy light-emitting layer 31 for emitting a color light, e.g., blue light by applying voltage to electrodes (not shown) of the light-emitting diode array 3. In addition, a green light-emitting thin film 32 produced by this invention is formed on the epitaxy light-emitting layer 31 of each green pixel (G), and a red light-emitting thin film 30 produced by this invention is formed on the epitaxy light-emitting layer 31 of each red pixel (R). For the red pixels, the red light-emitting thin film 30 absorbs the light emitted from epitaxy light-emitting layer 31 and then emits red light. For the green pixels, the green light-emitting thin film 32 absorbs the light emitted from epitaxy light-emitting layer 31 and then emits green light.

Embodiments of this invention provide head-up displays having a reflective film, which is a photoluminescent film differing from conventional reflective films. The reflective film produced by this invention has a high degree of transmission and visual perception of brightness and can avoid reflection mapping. Conventional reflective films of prior art have a limited view angle and the driver needs to sit within the view angle; otherwise the image of the reflective film cannot be viewed. On the contrary, this invention provides reflective films having no view angle so that they can be placed anywhere the windshield.

In addition, conventional light-emitting thin film is produced by directly coating phosphors on a substrate, and the produced light-emitting thin film has scattering problem due to grain boundaries of phosphors, so that objects cannot be clearly seen through the light-emitting thin film. In contrast, this invention utilizes the host to clad, disperse, and protect the light-emitting materials, so that the produced light-emitting thin films are uniform and have free of grain boundaries to avoid the scattering problem.

Furthermore, embodiments of this invention provide light-emitting thin films that can absorb a color light low sensible to human eye and emit another color light high sensible to human eye. Compared with prior art, this invention provides light-emitting thin films whose spectral sensitivity of human visual perception of brightness can be prompted under a same output power.

Moreover, embodiments of this invention provide light-emitting thin films that can be made by a solution process, such as spin coating, screen printing, ink jet printing, comma coating, or roll coating. The solution process is simple, compatible for most kinds of substrate, and capable of large area production. Furthermore, embodiments of this invention provide light-emitting thin films that are made of non-rare earth elements and therefor can be used to manufacture green products beneficial to future generations.

The intent accompanying this disclosure is to have each/all embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention. Corresponding or related structure and methods disclosed or referenced herein, and/or in any and all co-pending, abandoned or patented application(s) by any of the named inventor(s) or assignee(s) of this application and invention, are incorporated herein by reference in their entireties, wherein such incorporation includes corresponding or related structure (and modifications thereof) which may be, in whole or in part, (i) operable and/or constructed with, (ii) modified by one skilled in the art to be operable and/or constructed with, and/or (iii) implemented/made/used with or in combination with, any part(s) of the present invention according to this disclosure, that of the application and references cited therein, and the knowledge and judgment of one skilled in the art.

Conditional language, such as, among others, “can,” “could,” “might,” or “may,” unless specifically stated otherwise, or otherwise understood within the context as used, is generally intended to convey that embodiments include, and in other interpretations do not include, certain features, elements and/or steps. Thus, such conditional language is not generally intended to imply that features, elements and/or steps are in any way required for one or more embodiments, or interpretations thereof, or that one or more embodiments necessarily include logic for deciding, with or without user input or prompting, whether these features, elements and/or steps are included or are to be performed in any particular embodiment.

All of the contents of the preceding documents are incorporated herein by reference in their entireties. Although the disclosure herein refers to certain illustrated embodiments, it is to be understood that these embodiments have been presented by way of example rather than limitation. For example, any of the particulars or features set out or referenced herein, or other features, including method steps and techniques, may be used with any other structure(s) and process described or referenced herein, in whole or in part, in any combination or permutation as a non-equivalent, separate, non-interchangeable aspect of this invention. Corresponding or related structure and methods specifically contemplated and disclosed herein as part of this invention, to the extent not mutually inconsistent as will be apparent from the context, this specification, and the knowledge of one skilled in the art, including, modifications thereto, which may be, in whole or in part, (i) operable and/or constructed with, (ii) modified by one skilled in the art to be operable and/or constructed with, and/or (iii) implemented/made/used with or in combination with, any parts of the present invention according to this disclosure, include: (I) any one or more parts of the above disclosed or referenced structure and methods and/or (II) subject matter of any one or more of the inventive concepts set forth herein and parts thereof, in any permutation and/or combination, include the subject matter of any one or more of the mentioned features and aspects, in any permutation and/or combination.

Although specific embodiments have been illustrated and described, it will be appreciated by those skilled in the art that various modifications may be made without departing from the scope of the present invention, which is intended to be limited solely by the appended claims.

What is claimed is:

1. A light-emitting thin film, comprising:
one or more light-emitting materials, with each being capable of re-radiating photons or electromagnetic radiation after the absorption of photons or electromagnetic radiation; and
a host for eliminating grain boundaries and scattering of the one or more light-emitting materials.

2. The light-emitting thin film as recited in claim 1, wherein the one or more light-emitting materials comprise organic dyes made of non-rare earth elements, and the host keeps the polarity of the organic dyes and hence keeps absorption and radiation wavelength range as in the liquid form.

3. The light-emitting thin film as recited in claim 2, wherein the organic dyes comprise C545T or DCJTB.

4. The light-emitting thin film as recited in claim 1, wherein the host comprises silica gel or spin-on glass silicon dioxide.

5. The light-emitting thin film as recited in claim 1, wherein the host comprises a polymer.

6. The light-emitting thin film as recited in claim 5, wherein the polymer comprises polyvinylpyrrolidone (PVP), epoxy, polymethylmethacrylate (PMMA), or polydimethylsiloxane (PDMS).

7. The light-emitting thin film as recited in claim 1, wherein the one or more light-emitting materials comprise zinc oxide (ZnO).

8. The light-emitting thin film as recited in claim 1, wherein the light-emitting thin film is one layer of a multi-layered lens and is used to absorb blue light to protect an eye being damaged.

9. The light-emitting thin film as recited in claim 1, wherein the light-emitting thin film is placed above an epitaxy light-emitting layer of a pixel of a micro light-emitting diode array, and the light-emitting thin film absorb a first light emitted from the epitaxy light-emitting layer and then emit a second light.

10. A method to produce a light-emitting thin film, comprising the steps of:
dissolving one or more organic dyes and a host in a solvent to form a light-emitting solution;
forming the light-emitting solution on a substrate;
removing the solvent from the light-emitting solution to form a light-emitting thin film;
wherein each organic dye is capable of re-radiating photons or electromagnetic radiation after the absorption of photons or electromagnetic radiation, and the host eliminates grain boundaries and scattering of the one or more light-emitting materials and keeps the polarity and absorption and radiation wavelength range of the organic dyes as in the liquid form after the light-emitting thin film is formed.

11. The method as recited in claim 10, wherein the host comprises silica gel or liquid form of silicon dioxide, which is spin-coated on the substrate.

12. The method as recited in claim 11, wherein the host comprises a polymer.

13. The method as recited in claim 12, wherein the solvent comprises ethanol, chloroform, dichloromethane, or other solvents capable of dissolving the one or more organic dyes and polymer.

14. The method as recited in claim 12, wherein the organic dyes comprise non-rare earth elements.

15. The method as recited in claim 10, where method for forming the light-emitting solution on the substrate comprising spin coating, dip coating, ink jet printing, screen printing, comma coating, or roll coating.

16. The method as recited in claim 10, where the substrate is made of glass, epoxy, quartz, plastics, or other materials that will not react with the light-emitting thin film.

17. A head-up display, comprising:
a projection device for emitting a light beam;
a light-emitting thin film, comprising:
one or more light-emitting materials, with each capable of re-radiating photons or electromagnetic radiation after the absorption of photons or electromagnetic radiation; and
a host for eliminating grain boundaries and scattering of the one or more light-emitting materials.

18. The head-up display as recited in claim 17, wherein the one or more light-emitting materials comprise organic dyes made of non-rare earth elements, and the host keeps the polarity of the organic dyes and hence keeps absorption and radiation wavelength range as in the liquid form.

19. The head-up display as recited in claim 18, wherein the organic dyes comprise C545T or DCJTB.

20. The head-up display as recited in claim 18, wherein the host comprises silica gel or silicon dioxide formed by spin-on glass coating.

21. The head-up display as recited in claim 18, wherein the host comprises a polymer.

22. The head-up display as recited in claim 21, wherein the polymer comprises polyvinylpyrrolidone (PVP), epoxy, polymethylmethacrylate (PMMA), or polydimethylsiloxane (PDMS).

23. The head-up display as recited in claim 17, wherein the one or more light-emitting materials comprise zinc oxide (ZnO).
